(19) United States
(12) Patent Application Publication
(10) Pub. No.: US 2022/0081310 A1
(43) Pub. Date: Mar. 17, 2022

(54) TABULAR ALUMINA PARTICLE AND METHOD FOR MANUFACTURING TABULAR ALUMINA PARTICLE

(71) Applicant: DIC Corporation, Tokyo (JP)

(72) Inventors: Shaowei YANG, Qingdao, Shandong (CN); Masamichi HAYASHI, Sakura-shi (JP); Jianjun YUAN, Sakura-shi (JP); Yasuto MURATA, Sakura-shi (JP); Cheng LIU, Qingdao, Shandong (CN); Wei ZHAO, Qingdao, Shandong (CN)

(73) Assignee: DIC Corporation, Tokyo (JP)

(21) Appl. No.: 17/422,742

(22) PCT Filed: Jan. 25, 2019
(86) PCT No.: PCT/CN2019/073095

§ 371 Date: Jul. 13, 2021

(51) Int. Cl. C01F 7/30

(52) U.S. Cl. CPC C01F 7/30; C01P 2004/20; C01P 2002/60; C01P 2004/54

(57) ABSTRACT

Provided are a tabular alumina particle and a method for manufacturing it, wherein the particle has a major axis of 30 μm or more, a thickness of 3 μm or more, and an aspect ratio of 2 to 50 and contains molybdenum; and the method includes the steps of mixing an aluminum compound of 10% by mass or more in a form of Al₂O₃, a molybdenum compound of 20% by mass or more in a form of MoO₃, a potassium compound of 1% by mass or more in a form of K₂O, and silicon or a silicon compound of less than 1% by mass in a form of SiO₂, where total amount of raw materials is assumed to be 100% by mass in forms of oxides, so as to produce a mixture and firing the resulting mixture.

### TECHNICAL FIELD

The present invention relates to a tabular alumina particle and a method for manufacturing a tabular alumina particle.

### BACKGROUND ART

Alumina particles serving as inorganic fillers are used for various applications. In particular, tabular alumina particles have more excellent thermal characteristics, optical characteristics, and the like than spherical alumina particles, and further improvements in characteristics have been required.

In recent years, inorganic material synthesis that learns from nature and living things has been intensively researched. In particular, a flux method is a method for precipitating crystals from a solution of an inorganic compound or a metal at high temperature by utilizing wisdom in creating crystals (minerals) in the natural world. Examples of advantages of the flux method include that crystals can grow at temperatures much lower than the melting temperature of the target crystal, that crystals having very few defects grow, and that the particle shape can be controlled.

To date, technologies to produce α-alumina by such a flux method have been reported. For example, PTL 1 describes an invention related to an α-alumina macro-crystal that is a substantially hexagonal platelet single crystal, in which the diameter of the platelet is 2 to 20 μm, the thickness is 0.1 to 2 μm, and the ratio of the diameter to the thickness is 5 to 40. PTL 1 discloses that the α-alumina can be produced from transition alumina or hydrated alumina, and a flux. It is disclosed that the flux used at this time has a melting temperature of 800° C. or lower, contains chemically bonded fluorine, and melts, in a molten state, transition alumina or hydrated alumina.

Regarding production of tabular alumina, a method for manufacturing tabular alumina, in which silicon or a silicon compound containing a silicon element is used as a crystal control agent, is known (PTL 2). The technique disclosed in PTL 3 relates to octahedral alumina having a large particle diameter.

### CITATION LIST

### Patent Literature

[PTL 1]

Japanese Unexamined Patent Application Publication No. 03-131517

[PTL 2]

Japanese Unexamined Patent Application Publication No. 2016-222501

[PTL 3]

International Publication No. 2018/112810

### SUMMARY OF INVENTION

### Technical Problem

However, tabular alumina particles in the related art disclosed in PTL 1, PTL 2, and PTL 3 lack a feeling of brilliance when observed by the naked eye, and there is room for improvement from the viewpoint of optical characteristics.

The present invention was realized in consideration of such circumstances, and it is an object to provide a tabular alumina particle having excellent brilliance.

### Solution to Problem

In order to address the above-described problems, the present inventors performed intensive research. As a result, it was found that a tabular alumina particle having a predetermined shape had excellent brilliance, and the present invention was realized. That is, the present invention provides the following measures in order to solve the above-described problems.

(1) A tabular alumina particle having a major axis of 30 μm or more, a thickness of 3 μm or more, and an aspect ratio of 2 to 50 and containing molybdenum

(2) The tabular alumina particle according to (1) described above, further containing silicon

(3) The tabular alumina particle according to (2) described above, in which a molar ratio [Si]/[Al] of Si to Al, determined based on XPS analysis, is 0.001 or more

(4) The tabular alumina particle according to any one of (1) to (3) described above, in which a crystallite diameter of a (104) face is 150 nm or more, the crystallite diameter being calculated from a full-width at half-maximum of a peak corresponding to a (104) face of diffraction peaks obtained based on XRD analysis

(5) The tabular alumina particle according to any one of (1) to (4) described above, in which a crystallite diameter of a (113) face is 200 nm or more, the crystallite diameter being calculated from a full-width at half-maximum of a peak corresponding to a (113) face of diffraction peaks obtained based on XRD analysis

(6) The tabular alumina particle according to any one of (1) to (5) described above, in which a shape is a hexagonal-plate-like shape

(7) The tabular alumina particle according to any one of (1) to (6) described above, in which the tabular alumina particle is a single crystal

(8) A method for manufacturing a tabular alumina particle according to any one of (1) to (7) described above, the method including the steps of mixing an aluminum compound containing aluminum element of 10% by mass or more in a form of Al₂O₃, a molybdenum compound containing molybdenum element of 20% by mass or more in a form of MoO₃, a potassium compound containing potassium element of 1% by mass or more in a form of K₂O, and silicon or a silicon compound containing silicon element of less than 1% by mass in a form of SiO₂, where a total amount of raw materials is assumed to be 100% by mass in forms of oxides, so as to produce a mixture and firing the resulting mixture

(9) The method for manufacturing a tabular alumina particle according to (8) described above, in which the mixture further includes an yttrium compound containing an yttrium element

### Advantageous Effects of Invention

According to the present invention, a tabular alumina particle having excellent brilliance can be provided because the tabular alumina particle has a predetermined shape.

### BRIEF DESCRIPTION OF DRAWINGS

FIG. 1 is an SEM image of tabular alumina particles obtained in an example.

### DESCRIPTION OF EMBODIMENTS

A tabular alumina particle and a method for manufacturing a tabular alumina particle according to an embodiment of the present invention will be described below in detail.

[Tabular Alumina Particle]

Regarding the shape of the tabular alumina particle according to the embodiment, the major axis is 30 μm or more, the thickness is 3 μm or more, and the aspect ratio is 2 to 50. Preferably, the crystal type is an α-type, as described later (α-alumina is preferable). In addition, the tabular alumina particle according to the embodiment contains molybdenum. Further, the tabular alumina particle according to the embodiment may contain impurities derived from raw materials and the like as long as the effects of the present invention are not impaired. In this regard, the tabular alumina particle may further contain an organic compound and the like.

The tabular alumina particle according to the embodiment can have excellent brilliance by having the above-described shape. The tabular alumina particles in the related art described in PTL 1 to PTL 3 do not satisfy the above-described factors of the major axis, the thickness, and the aspect ratio. Consequently, alumina particles in the related art lack a feeling of brilliance probably due to a non-tabular shape or a small particle size. Meanwhile, the octahedral alumina particle described in PTL 3 has very poor brilliance when compared with the tabular alumina particle according to the embodiment of the present invention, where the particle diameters are substantially the same. The reason for this is conjectured to be that, regarding the octahedral alumina, incident light is not totally reflected in contrast to the tabular alumina but is reflected at some surfaces (diffused reflection occurs).

The tabular alumina particle according to the embodiment is tabular and has a large particle size. Therefore, it is conjectured that a light reflection surface is large and intense brilliance can be exhibited. In this regard, “particle size” in the present specification takes values of a major axis and a thickness into consideration. “Brilliance” means a visual recognition possibility of glittering light that is generated due to reflection of light by the alumina particle.

“Tabular” in the present invention means to have an aspect ratio of 2 or more, where the aspect ratio is determined by dividing the major axis of an alumina particle by the thickness. In this regard, in the present specification, “thickness of alumina particle” means an arithmetic average value of a measured thicknesses of at least 50 alumina particles arbitrarily selected from an image obtained by a scanning electron microscope (SEM). “Major axis of alumina particle” means an arithmetic average value of a measured major axes of at least 50 tabular alumina particles arbitrarily selected from an image obtained by a scanning electron microscope (SEM). “Major axis” means a maximum length of distances between two points on a border line of an alumina particle.

Regarding the shape of the tabular alumina particle according to the embodiment, the major axis is 30 μm or more, the thickness is 3 μm or more, and the aspect ratio that is the ratio of the major axis to the thickness is 2 to 50. The major axis of the tabular alumina particle is 30 μm or more and, thereby, an excellent feeling of brilliance can be exhibited. The thickness of the tabular alumina particle is 3 μm or more and, thereby, an excellent feeling of brilliance can be exhibited. In addition, excellent mechanical strength can be provided. The aspect ratio of the tabular alumina particle is 2 or more and, thereby, an excellent feeling of brilliance can be exhibited. In addition, two-dimensional orientation characteristics can be provided. The aspect ratio of the tabular alumina particle is 50 or less and, thereby, excellent mechanical strength can be provided. The tabular alumina particles according to the embodiment can further have a more excellent feeling of brilliance, mechanical strength, and two-dimensional orientation characteristics by improving uniformity of the shape, the size, and the like. Therefore, the major axis is preferably 50 to 200 μm, the thickness is preferably 5 to 60 μm, and the aspect ratio that is the ratio of the major axis to the thickness is preferably 3 to 30.

Regarding the above-described preferable shape of the alumina particle, conditions of thickness, average particle diameter, and aspect ratio can be arbitrarily combined as long as the shape is tabular.

The tabular alumina particle according to the embodiment may have a circular-plate-like shape or an elliptical-plate-like shape. However, it is preferable that the particle shape be a polygonal-plate-like shape, for example, hexagonal, heptagonal, or octagonal, from the viewpoints of optical characteristics, handleability, ease of production, and the like. A hexagonal-plate-like shape is more preferable from the viewpoint of exhibition of particularly excellent brilliance.

Here, hexagonal-plate-like tabular alumina particle is assumed to be a particle which has an aspect ratio of 2 or more and in which the number of sides having a length of 0.6 or more (including the longest side) relative to the length of the longest side of 1 is 6 and, in addition, the total length of the sides having a length of 0.6 or more is 0.9 L relative to the length of the perimeter of 1 L. In connection with the observation conditions, when it is clear that aside has become not straight because of an occurrence of chipping of the particle, the side may be measured after being revised to a straight line. Likewise, even when a portion corresponding to the corner of the hexagon is slightly rounded, measurement may be performed after the corner is revised to an intersection of straight lines. The aspect ratio of the hexagonal-plate-like tabular alumina particle is preferably 3 or more. The major axis of the hexagonal-plate-like tabular alumina particle is preferably 50 μm or more.

In the tabular alumina particle according to the embodiment, a proportion of the hexagonal-plate-like tabular alumina particle is preferably 30% or more by calculation on a number basis, where the total number of tabular alumina particles is assumed to be 100%, and particularly preferably 80% or more because brilliance can be enhanced more due to an increase in regular reflection of light by the hexagonal-plate-like shape.

The crystallite diameter of the (104) face of the tabular alumina particle according to the embodiment is preferably 150 nm or more, more preferably within the range of 200 to 700 nm, and further preferably within the range of 300 to 600 nm. In this regard, the size of the crystal domain of the (104) face corresponds to the crystallite diameter of the (104) face. It is considered that, as the crystallite diameter increases, the light reflection surface increases and high brilliance can be exhibited. The crystallite diameter of the (104) face of the tabular alumina particle can be controlled by appropriately setting the condition for a manufacturing method described later. In the present specification, the value calculated, by using Scherrer equation, based on the full-width at half-maximum of a peak (peak that appears at approximately 2θ=35.2 degrees) that is attributed to the (104) face and that is measured by using X-ray diffraction (XRD) is adopted as the value of the “crystallite diameter of the (104) face”.

Meanwhile, the crystallite diameter of the (113) face of the tabular alumina particle according to the embodiment is preferably 200 nm or more, more preferably within the range of 250 to 1,000 nm, and further preferably within the range of 300 to 500 nm. In this regard, the size of the crystal domain of the (113) face corresponds to the crystallite diameter of the (113) face. It is considered that, as the crystallite diameter increases, the light reflection surface increases and high brilliance can be exhibited. The crystallite diameter of the (113) face of the tabular alumina particle can be controlled by appropriately setting the condition for a manufacturing method described later. In the present specification, the value calculated, by using Scherrer equation, based on the full-width at half-maximum of a peak (peak that appears at approximately 2θ=43.4 degrees) that is attributed to the (113) face and that is measured by using X-ray diffraction (XRD) is adopted as the value of the “crystallite diameter of the (113) face”.

The XRD analysis is performed under the same condition as the measurement condition cited in the example described later or a compatible condition for obtaining the same measurement result.

Preferably, the tabular alumina particle according to the embodiment is a single crystal. The single crystal means a crystal grain composed of a single composition in which unit lattices are orderly arranged. In many cases, a high-quality crystal is transparent and generates reflected light. If part of crystal is stepwise or a surface is constricted at an acute angle, it is conjectured that the crystal is a polycrystal in which a plurality of crystal components overlap one another. The measurement for determining whether a particle is a single crystal is performed under the same condition as the measurement condition cited in the example described later or a compatible condition for obtaining the same measurement result. The tabular alumina particle being a single crystal refers to the particle having high quality, and it is conjectured that excellent brilliance is exhibited.

The thickness, the major axis, the aspect ratio, the shape, the crystallite diameter, and the like of the tabular alumina particle according to the embodiment can be controlled by selecting, for example, the ratio of the aluminum compound, the molybdenum compound, the potassium compound, the silicon or silicon compound, and the metal compound used.

The tabular alumina particle based on α-alumina according to the embodiment may be obtained by any manufacturing method as long as the major axis is 30 μm or more, the thickness is 3 μm or more, the aspect ratio is 2 to 50, and molybdenum is contained. Preferably, the tabular alumina particle is obtained by firing the aluminum compound in the presence of the molybdenum compound, the potassium compound, and the silicon or silicon compound because the tabular alumina particle having a higher aspect ratio and excellent brilliance can be produced. Further preferably, the tabular alumina particle is obtained by firing the aluminum compound in the presence of the molybdenum compound, the potassium compound, the silicon or silicon compound, and the metal compound as will be described later. The metal compound may be used in combination or may not be used. However, the crystal can be more simply controlled by using the metal compound in combination. Regarding the metal compound, it is recommended to use an yttrium compound for the purpose of facilitating crystal growth such that resulting α-type tabular alumina particles have uniform crystal shapes, sizes, and the like.

In the above-described manufacturing method, the molybdenum compound is used as a flux agent. In the present specification, the manufacturing method in which the molybdenum compound is used as the flux agent may also be simply referred to as a “flux method” hereafter. The flux method will be described later in detail. In this regard, the molybdenum compound reacts with the potassium compound by such firing so as to form potassium molybdate. At the same time, the molybdenum compound reacts with the aluminum compound so as to form aluminum molybdate and, thereafter, aluminum molybdate is decomposed in the presence of potassium molybdate, crystal growth advances in the presence of the silicon or silicon compound and, thereby, the tabular alumina particle having a large particle size can be obtained. That is, when an alumina particle is produced via aluminum molybdate serving as an intermediate, if potassium molybdate is present, the alumina particle having a large particle size is obtained. In addition, it is considered that the molybdenum compound is taken into the tabular alumina particle during crystal growth. The above-described flux method is one type of flux slow cooling method, and it is considered that crystal growth advances in liquid phase potassium molybdate. Further, potassium molybdate can be readily recovered by washing with water, ammonia water, or an inorganic base aqueous solution, for example, sodium hydroxide aqueous solution or potassium hydroxide aqueous solution, and be reused.

The alumina particle has a high α-crystal ratio and becomes an euhedral crystal by utilizing the molybdenum compound, the potassium compound, and the silicon or silicon compound in the above-described production of the tabular alumina particle. Therefore, excellent dispersibility, mechanical strength, and brilliance can be realized.

The shape of the tabular alumina particle can be controlled by the ratio of, for example, the molybdenum compound, the potassium compound, and the silicon or silicon compound used and, in particular, be controlled by the ratio of the molybdenum compound and the silicon or silicon compound used. The amount of molybdenum and the amount of silicon contained in the tabular alumina particle and a preferable ratio of the raw materials used will be described later in detail.

[Alumina]

“Alumina” contained in the tabular alumina particle according to the embodiment is aluminum oxide and may be transition alumina having a crystal form of, for example, γ, δ, θ, and k, or the transition alumina may contain an alumina hydrate. However, being basically α-crystal form (α-type) is preferable because of more excellent mechanical strength or brilliance. The α-crystal form is a dense crystal structure of alumina and there are advantages in an improvement of mechanical strength or brilliance of the tabular alumina according to the present invention.

It is preferable that the α-crystallization rate approach 100% as much as possible because properties intrinsic to the α-crystal form are readily exhibited. The α-crystallization rate of the tabular alumina particle according to the embodiment is, for example, 90% or more, preferably 95% or more, and more preferably 99% or more.

[Molybdenum]

Meanwhile, the tabular alumina particle according to the embodiment contains molybdenum. The molybdenum is derived from the molybdenum compound used as the flux agent.

Molybdenum has a catalytic function and an optical function. In addition, when molybdenum is used in a manufacturing method as described later, a tabular alumina particle having a major axis of 30 μm or more, a thickness of 3 μm or more, and an aspect ratio of 2 to 50, containing molybdenum, and having excellent brilliance can be produced. Further, when the amount of molybdenum used is increased, a hexagonal-plate-like alumina particle having a large particle size and a large crystallite diameter is readily obtained, and the resulting alumina particle tends to have further excellent brilliance. In this regard, application to use for an oxidation reaction catalyst or an optical material may become possible by utilizing characteristics of molybdenum contained in the tabular alumina particle.

There is no particular limitation regarding the molybdenum, and molybdenum oxide, molybdenum compound that is partly reduced, or the like may be used other than the molybdenum metal. It is considered that molybdenum in the form of MoO₃ is contained in the tabular alumina particle but molybdenum in the form of MoO₂, MoO, or the like other than MoO₃ may be contained in the tabular alumina particle.

There is no particular limitation regarding the form of molybdenum contained. Molybdenum may be contained in the form of being attached to the surface of the tabular alumina particle or in the form of being substituted for some of aluminum in the crystal structure of alumina, or these may be combined.

The content of molybdenum as molybdenum trioxide is preferably 10% by mass or less relative to 100% by mass of tabular alumina particle according to the embodiment, more preferably 0.1% to 5% by mass when the firing temperature, the firing time, and the sublimation rate of molybdenum are adjusted, and further preferably 0.3% to 1% by mass. The molybdenum content of 10% by mass or less is preferable because the quality of α-single crystal of alumina is improved. The molybdenum content of 0.1% by mass or more is preferable because the shape of the resulting tabular alumina particle improves the brilliance.

The molybdenum content can be determined by XRF analysis. The XRF analysis is performed under the same condition as the measurement condition cited in the example described later or a compatible condition for obtaining the same measurement result.

[Silicon]

The tabular alumina particle according to the embodiment may further contain silicon. The silicon is derived from the silicon or silicon compound used as the raw material. When silicon is used in the manufacturing method described later, a tabular alumina particle having a major axis of 30 μm or more, a thickness of 3 μm or more, and an aspect ratio of 2 to 50, containing silicon, and having excellent brilliance can be produced. Further, when the amount of silicon used is decreased to some extent, a hexagonal-plate-like alumina particle having a large particle size and a large crystallite diameter is readily obtained, and the resulting alumina particle tends to have further excellent brilliance. A preferable amount of silicon used will be described later.

The tabular alumina particle according to the embodiment may contain silicon in the surface layer. In this regard, “surface layer” means a layer within 10 nm from the surface of the tabular alumina particle according to the embodiment. This distance corresponds to the detection depth of XPS used for the measurement in the example.

In the tabular alumina particle according to the embodiment, silicon may be unevenly distributed in the surface layer. In this regard, “being unevenly distributed in the surface layer” means a state in which the mass of silicon per unit volume of the surface layer is greater than the mass of silicon per unit volume of the portion other than the surface layer. Uneven distribution of silicon in the surface layer can be identified by comparing the result of surface analysis based on XPS and the result of overall analysis based on XRF as cited in the example described later.

Silicon included in the tabular alumina particle according to the embodiment may be a silicon simple substance or be silicon in the silicon compound. The tabular alumina particle according to the embodiment may contain at least one selected from a group consisting of Si, SiO₂, and SiO as the silicon or silicon compound, and the above-described substance may be included in the surface layer. Preferably, the tabular alumina particle according to the embodiment contain substantially no mullite.

The tabular alumina particle according to the embodiment contains silicon in the surface layer and, therefore, Si is detected by XPS analysis. The tabular alumina particle according to the embodiment has a value of a molar ratio [Si]/[Al] of Si to Al, determined based on XPS analysis, is preferably 0.001 or more, more preferably 0.01 or more, and further preferably 0.02 or more. The entire surface of the tabular alumina particle may be covered with the silicon or silicon compound, or at least part of the surface of the tabular alumina particle may be covered with the silicon or silicon compound.

There is no particular limitation regarding the upper limit of the value of the molar ratio [Si]/[Al] determined based on XPS analysis, and 0.4 or less is preferable, 0.11 or less is more preferable, and 0.06 or less is further preferable.

The tabular alumina particle according to the embodiment has a value of the molar ratio [Si]/[Al] of Si to Al, determined based on XPS analysis, of preferably 0.001 or more and 0.4 or less, more preferably 0.01 or more and 0.11 or less, and further preferably 0.02 or more and 0.06 or less.

The tabular alumina particle according to the embodiment having a value of the molar ratio [Si]/[Al], determined based on XPS analysis, within the above-described range is preferable because of having an appropriate amount of Si contained in the surface layer, being tabular, and having a large particle size and more excellent brilliance.

The XPS analysis is performed under the same condition as the measurement condition cited in the example described later or a compatible condition for obtaining the same measurement result.

The tabular alumina particle according to the embodiment contains silicon and, therefore, Si is detected by XRF analysis. The tabular alumina particle according to the embodiment has the value of the molar ratio [Si]/[Al] of Si to Al, determined based on XRF analysis, that is preferably 0.0003 or more and 0.01 or less, more preferably 0.0005 or more and 0.0025 or less, and further preferably 0.0006 or more and 0.001 or less.

The tabular alumina particle according to the embodiment having a value of the molar ratio [Si]/[Al], determined based on XRF analysis, within the above-described range is preferable because of having an appropriate amount of Si, being tabular, and having a large particle size and more excellent brilliance.

The tabular alumina particle according to the embodiment contains silicon corresponding to the silicon or silicon compound used in the manufacturing method. The content of silicon as silicon dioxide is preferably 10% by mass or less relative to 100% by mass of tabular alumina particle according to the embodiment, more preferably 0.001% to 3% by mass, further preferably 0.01% to 1% by mass, and particularly preferably 0.03% to 0.3% by mass. The tabular alumina particle having a content of silicon within the above-described range is preferable because of having an appropriate amount of Si, being tabular, and having a large particle size and more excellent brilliance.

The XRF analysis is performed under the same condition as the measurement condition cited in the example described later or a compatible condition for obtaining the same measurement result.

[Incidental impurities]

The tabular alumina particle may contain incidental impurities.

Incidental impurities refer to impurities that are derived from the potassium compound and the metal compound used in the production, present in the raw materials, or incidentally mixed into the tabular alumina particle in the production step, that are essentially unnecessary, and that have no influence on the characteristics of the tabular alumina particle.

There is no particular limitation regarding the incidental impurities. Examples of the incidental impurities include potassium, magnesium, calcium, strontium, barium, scandium, yttrium, lanthanum, cerium, and sodium. These incidental impurities may be contained alone, or at least two types may be contained.

The content of the incidental impurities in the tabular alumina particle is preferably 10,000 ppm or less, more preferably 1,000 ppm or less, and further preferably 10 to 500 ppm relative to the mass of the tabular alumina particle.

[Other Atoms]

Other atoms refer to atoms intentionally added to the tabular alumina particle for the purpose of providing mechanical strength or electrical and magnetic functions within the bounds of not impairing the effects of the present invention.

There is no particular limitation regarding the other atoms, and examples of the other atoms include zinc, manganese, calcium, strontium, and yttrium. These other atoms may be used alone, or at least two types may be used in combination.

The content of the other atoms in the tabular alumina particle is preferably 5% by mass or less and more preferably 2% by mass or less relative to the mass of the tabular alumina particle.

[Organic Compound]

In an embodiment, the tabular alumina particle may contain an organic compound. The organic compound is present in the surface portion of the tabular alumina particle and has a function of adjusting the surface properties of the tabular alumina particle. For example, the tabular alumina particle containing the organic compound in the surface portion has improved affinity for a resin and, therefore, the tabular alumina particle can perform functions as a filler to the greatest extent.

There is no particular limitation regarding the organic compound, and examples of the organic compound include organic silane, an alkylphosphonic acid, and a polymer.

Examples of the organic silane include alkyltrimethoxysilanes or alkyltrichlorosilanes having a carbon number of an alkyl group of 1 to 22 such as methyltrimethoxysilane, dimethyldimethoxysilane, ethyltrimethoxysilane, ethyltriethoxysilane, n-propyltrimethoxysilane, n-propyltriethoxysilane, iso-propyltrimethoxysilane, iso-propyltriethoxysilane, pentyltrimethoxysilane, and hexyltrimethoxysilane, 3,3,3-trifluoropropyltrimethoxysilane, (tridecafluoro-1,1,2,2-tetrahydrooctyl)trichlorosilane, phenyltrimethoxysilane, phenyltriethoxysilane, p-chloromethylphenyltrimethoxysilane, and p-chloromethylphenyltriethoxysilane.

Examples of the phosphonic acid include methylphosphonic acid, ethylphosphonic acid, propylphosphonic acid, butylphosphonic acid, pentylphosphonic acid, hexylphosphonic acid, heptylphosphonic acid, octylphosphonic acid, decylphosphonic acid, dodecylphosphonic acid, octadecylphosphonic acid, 2-ethylhexylphosphonic acid, cyclohexylmethylphosphonic acid, cyclohexylethylphosphonic acid, benzylphosphonic acid, phenylphosphonic acid, and dedecylbenzenephosphonic acid.

Regarding the polymer, for example, poly(meth)acrylates are suitable for use. Specific examples of the polymer include a polymethyl (meth)acrylate, a polyethyl (meth)acrylate, a polybutyl (meth)acrylate, a polybenzyl (meth)acrylate, a polycyclohexyl (meth)acrylate, a poly(t-butyl (meth)acrylate), a polyglycidyl (meth)acrylate, and a polypentafluoropropyl (meth)acrylate. In addition, general-purpose polymers, for example, a polystyrene, a polyvinyl chloride, a polyvinyl acetate, an epoxy resin, a polyester, a polyimide, and a polycarbonate may be included.

In this regard, the above-described organic compounds may be contained alone, or at least two types may be contained.

There is no particular limitation regarding the form of the organic compound contained. The organic compound may be bonded to the alumina by a covalent bond or may cover the alumina.

The content of the organic compound is preferably 20% by mass or less and further preferably 10% to 0.01% by mass relative to the mass of the tabular alumina particle. The content of the organic compound being 20% by mass or less is preferable because the physical properties resulting from the tabular alumina particle can readily be realized.

[Method for Manufacturing Tabular Alumina Particle]

There is no particular limitation regarding the method for manufacturing the tabular alumina particle according to the embodiment, and a known technique can be appropriately applied. It is preferable that a manufacturing method based on the flux method in which the molybdenum compound is used be applied from the viewpoint of appropriate controllability of alumina having a high α-crystallization rate at relatively low temperature.

In more detail, a preferable method for manufacturing the tabular alumina particle includes a step (firing step) of firing the aluminum compound in the presence of the molybdenum compound, the potassium compound, and the silicon or silicon compound. The firing step may be a step of firing a mixture obtained in a step (mixing step) of obtaining the mixture that is a target for firing. Preferably, the mixture contains a metal compound as described later. Preferably, the metal compound is an yttrium compound.

[Mixing Step]

The mixing step is a step of mixing raw materials, for example, the aluminum compound, the molybdenum compound, the potassium compound, and the silicon or silicon compound, so as to produce the mixture. The content of the mixture will be described below.

[Aluminum Compound]

The aluminum compound is a raw material for the tabular alumina particle according to the embodiment.

There is no particular limitation regarding the aluminum compound as long as the alumna particle is produced by heat treatment. Examples of the aluminum compound include aluminum metal, aluminum sulfide, aluminum nitride, aluminum fluoride, aluminum chloride, aluminum bromide, aluminum iodide, aluminum sulfate, sodium aluminum sulfate, potassium aluminum sulfate, ammonium aluminum sulfate, aluminum nitrate, aluminum aluminate, aluminum silicate, aluminum phosphate, aluminum lactate, aluminum laurate, aluminum stearate, aluminum oxalate, aluminum acetate, aluminum subacetate, aluminum propoxide, aluminum butoxide, aluminum hydroxide, boehmite, pseudo-boehmite, transition alumina (γ-alumina, δ-alumina, θ-alumina, and the like), α-alumina, and mixed alumina having at least two crystal phases. In particular, transition alumina, boehmite, pseudo-boehmite, aluminum hydroxide, aluminum chloride, aluminum sulfate, and aluminum nitrate and hydrates of these are used preferably, and transition alumina, boehmite, pseudo-boehmite, and aluminum hydroxide are used more preferably. When αalumina is obtained as the tabular alumina particle, it is preferable that alumina containing substantially no α-alumina, for example, relatively inexpensive transition alumina containing γ-alumina as a primary component be used as the above-described raw material. As described above, the tabular alumina particle having a specific shape and size different from the shape and the size of the raw material can be obtained as a product by firing the raw material.

The above-described aluminum compounds may be used alone, or at least two types may be used in combination.

Regarding the aluminum compound, a commercially available product may be used, or in-house preparation may be performed.

When the aluminum compound is prepared in-house, for example, the alumina hydrate or the transition alumina having high structural stability at high temperature can be prepared by neutralizing an aluminum aqueous solution. In more detail, the alumina hydrate can be prepared by neutralizing an acidic aqueous solution of aluminum by a base, and the transition alumina can be prepared by heat-treating the alumina hydrate obtained as described above. In this regard, the thus obtained alumina hydrate or transition alumina has high structural stability at high temperature and, therefore, the tabular alumina particle having a large particle size tends to be obtained by firing in the presence of the molybdenum compound and the potassium compound.

There is no particular limitation regarding the shape of the aluminum compound, and any one of a spherical structure, an amorphous structure, a structure having an aspect ratio (for example, wire, fiber, ribbon, or tube), a sheet, and the like is suitable for use.

There is no particular limitation regarding the average particle diameter of the aluminum compound, and 5 nm to 10,000 μm is preferable.

The aluminum compound may constitute a composite with an organic compound. Examples of the composite include an organic-inorganic composite obtained by modifying the aluminum compound by using organic silane, a composite of the aluminum compound with a polymer adsorbed, and a composite in which the aluminum compound is covered with an organic compound. When these composites are used, there is no particular limitation regarding the content of the organic compound. However, 60% by mass or less is preferable, and 30% by mass or less is more preferable.

The molar ratio (molybdenum element/aluminum element) of the molybdenum element in the molybdenum compound to the aluminum element in the aluminum compound is preferably 0.01 to 3.0 and more preferably 0.1 to 1.0. For the purpose of favorably advancing crystal growth with good productivity, 0.30 to 0.70 is further preferable. The molar ratio (molybdenum element/aluminum element) being within the above-described range is preferable because the tabular alumina particle having a large particle size can be obtained.

[Molybdenum Compound]

There is no particular limitation regarding the molybdenum compound, and examples of the molybdenum compound include molybdenum metal, molybdenum oxide, molybdenum sulfide, lithium molybdate, sodium molybdate, potassium molybdate, calcium molybdate, ammonium molybdate, H₃PMo₁₂O₄₀, and H₃SiMo₁₂O₄₀. In this regard, the molybdenum compounds include isomers. For example, molybdenum oxide may be molybdenum(IV) dioxide (MoO₂) or molybdenum(VI) trioxide (MoO₃). Meanwhile, potassium molybdate has a structural formula of K₂MoₙO₃ₙ₊₁, and n may be 1, 2, or 3. In particular, molybdenum trioxide, molybdenum dioxide, ammonium molybdate, and potassium molybdate are preferable, and molybdenum trioxide is more preferable.

In this regard, the above-described molybdenum compounds may be used alone, or at least two types maybe used in combination.

In addition, potassium molybdate (K₂MoₙO₃ₙ₊₁, n=1 to 3) contains potassium and, therefore, may have functions as the potassium compound described later.

[Potassium Compound]

There is no particular limitation regarding the potassium compound, and examples of the potassium compound include potassium chloride, potassium chlorite, potassium chlorate, potassium sulfate, potassium hydrogen sulfate, potassium sulfite, potassium hydrogen sulfite, potassium nitrate, potassium carbonate, potassium hydrogen carbonate, potassium acetate, potassium oxide, potassium bromide, potassium bromate, potassium hydroxide, potassium silicate, potassium phosphate, potassium hydrogen phosphate, potassium sulfide, potassium hydrogen sulfide, potassium molybdate, and potassium tungstate. In this regard, the above-described potassium compounds include isomers in the same manner as the molybdenum compounds. In particular, potassium carbonate, potassium hydrogen carbonate, potassium oxide, potassium hydroxide, potassium chloride, potassium sulfate, and potassium molybdate are used preferably, and potassium carbonate, potassium hydrogen carbonate, potassium chloride, potassium sulfate, and potassium molybdate are used more preferably.

The above-described potassium compounds may be used alone, or at least two types may be used in combination.

In addition, in the same manner as the above description, potassium molybdate contains molybdenum and, therefore, may have functions as the molybdenum compound.

Regarding the potassium compound that is used when the raw materials are charged or that is generated by a reaction during a temperature increase process of firing, a water-soluble potassium compound, for example, potassium molybdate, is not vaporized even in the firing temperature range and can readily be recovered by washing after the firing. As a result, the amount of the molybdenum compound released outside a firing furnace is reduced, and the production cost can be reduced to a great extent.

The molar ratio (molybdenum element/potassium element) of the molybdenum element in the molybdenum compound to the potassium element in the potassium compound is preferably 5 or less and more preferably 0.01 to 3. Because the production cost can be still more reduced, 0.5 to 1.5 is further preferable. The molar ratio (molybdenum element/potassium element) being within the above-described range is preferable because the tabular alumina particle having a large particle size can be obtained.

[Silicon or Silicon Compound]

There is no particular limitation regarding the silicon or silicon compound containing silicon element, and known materials can be used. Specific examples of the silicon or silicon compound include artificial synthetic silicon compounds, for example, silicon metal, an organic silane, a silicon resin, silicon fine particles, silica gel, mesoporous silica, SiC, and mullite; and natural silicon compounds, for example, biosilica. In particular, preferably, an organic silane, a silicon resin, and silicon fine particles are used from the viewpoint of performing more uniform combination or mixing with the aluminum compound. In this regard, the silicon or silicon compounds may be used alone, or at least two types may be used in combination.

The rate of the silicon compound added relative to the aluminum atom in the aluminum compound, on a mass basis, is preferably 0.01% to 1% by mass and more preferably 0.03% to 0.4% by mass. The rate of the silicon compound added being within the above-described range is preferable because the tabular alumina particle having a large thickness and excellent brilliance can be obtained.

The molar ratio (silicon element/aluminum element) of the silicon element in the silicon compound to the aluminum element in the aluminum compound is preferably 0.0001 to 0.01, more preferably 0.0002 to 0.005, and further preferably 0.0003 to 0.003. The molar ratio (silicon element/aluminum element) being within the above-described range is preferable because the tabular alumina particle having a large particle size can be obtained.

There is no particular limitation regarding the shape of the silicon or silicon compound containing silicon element, and any one of a spherical structure, an amorphous structure, a structure having an aspect ratio (for example, wire, fiber, ribbon, or tube), a sheet, and the like is suitable for use.

[Metal Compound]

The metal compound can have a function of facilitating crystal growth of alumina, as described later. The metal compound may be used in the firing, as the situation demands. In this regard, the metal compound has a function of facilitating crystal growth of α-alumina and, therefore, is not indispensable for producing the tabular alumina particle according to the present invention.

There is no particular limitation regarding the metal compound, and it is preferable that the metal compound contain at least one selected from a group consisting of metal compounds of group II and metal compounds of group III.

Examples of the metal compounds of group II include a magnesium compound, a calcium compound, a strontium compound, and a barium compound.

Examples of the metal compounds of group III include a scandium compound, an yttrium compound, a lanthanum compound, and a cerium compound.

The above-described metal compound refers to an oxide, a hydroxide, a carbonate, or a chloride of a metal element. Examples of the yttrium compound include yttrium oxide (Y₂O₃), yttrium hydroxide, and yttrium carbonate. In particular, it is preferable that the metal compound be an oxide of a metal element. These metal compounds include isomers.

In particular, metal compounds of period 3 elements, metal compounds of period 4 elements, metal compounds of period 5 elements, and metal compounds of period 6 elements are preferable, metal compounds of period 4 elements and metal compounds of period 5 elements are more preferable, and metal compounds of period 5 elements are further preferable. Specifically, it is preferable that the magnesium compound, the calcium compound, the yttrium compound, and the lanthanum compound be used, it is more preferable that the magnesium compound, the calcium compound, and the yttrium compound be used, and it is particularly preferable that the yttrium compound be used.

The rate of the metal compound added relative to the aluminum atom in the aluminum compound, on a mass basis, is preferably 0.02% to 20% by mass and more preferably 0.1% to 20% by mass. The rate of the metal compound added being 0.02% by mass or more is preferable because crystal growth of α-alumina containing molybdenum advances favorably. Meanwhile, the rate of the metal compound added being 20% by mass or less is preferable because the tabular alumina particle having a low content of impurities derived from the metal compound can be obtained.

[Yttrium]

When the aluminum compound is fired in the presence of the yttrium compound serving as the metal compound, crystal growth advances more favorably during the firing step so as to generate α-alumina and a water-soluble yttrium compound. At this time, the water-soluble yttrium compound tends to localize on the surface of the α-alumina that is the tabular alumina particle. The yttrium compound can be removed from the tabular alumina particle by performing washing by, for example, water, alkaline water, or warmed liquids of these.

There is no particular limitation regarding the amounts of the aluminum compound, the molybdenum compound, the potassium compound, and the silicon or silicon compound used. Preferably, a mixture may be produced by mixing the aluminum compound of 10% by mass or more in the form of Al₂O₃, the molybdenum compound of 20% by mass or more in the form of MoO₃, the potassium compound of 1% by mass or more in the form of K₂O, and the silicon or silicon compound of less than 1% by mass in the form of SiO₂, where the total amount of the raw materials is assumed to be 100% by mass in the forms of oxides, and the resulting mixture may be fired. More preferably, a mixture may be produced by mixing the aluminum compound of 20% by mass or more and 70% by mass or less in the form of Al₂O₃, the molybdenum compound of 30% by mass or more and 80% by mass or less in the form of MoO₃, the potassium compound of 5% by mass or more and 30% by mass or less in the form of K₂O, and the silicon or silicon compound of 0.001% by mass or more and 0.3% by mass or less in the form of SiO₂, where the total amount of the raw materials is assumed to be 100% by mass in the forms of oxides, and the resulting mixture may be fired because the content of hexagonal-plate-like alumina can be further increased. Further preferably, a mixture may be produced by mixing the aluminum compound of 25% by mass or more and 40% by mass or less in the form of Al₂O₃, the molybdenum compound of 45% by mass or more and 70% by mass or less in the form of MoO₃, the potassium compound of 10% by mass or more and 20% by mass or less in the form of K₂O, and the silicon or silicon compound of 0.01% by mass or more and 0.1% by mass or less in the form of SiO₂, where the total amount of the raw materials is assumed to be 100% by mass in the forms of oxides, and the resulting mixture may be fired. Particularly preferably, a mixture may be produced by mixing the aluminum compound of 35% by mass or more and 40% by mass or less in the form of Al₂O₃, the molybdenum compound of 45% by mass or more and 65% by mass or less in the form of MoO₃, the potassium compound of 10% by mass or more and 20% by mass or less in the form of K₂O, and the silicon or silicon compound of 0.02% by mass or more and 0.08% by mass or less in the form of SiO₂, where the total amount of the raw materials is assumed to be 100% by mass in the forms of oxides, and the resulting mixture may be fired because the content of hexagonal-plate-like alumina can be increased to the maximum and crystal growth advances more favorably.

The tabular alumina particle having a plate-like form and a large particle size and more excellent brilliance can be produced by mixing various compounds within the above-described ranges. In particular, tendencies to increase the amount of molybdenum used and to decrease the amount of silicon used to some extent can increase the particle size and the crystallite diameter and the hexagonal-plate-like alumina particle is readily obtained. When various compounds are mixed within the above-described further preferable ranges, the hexagonal-plate-like alumina particle is readily obtained, the content of the hexagonal-plate-like alumina particle can be increased, and the resulting alumina particle tends to have further excellent brilliance.

When the above-described mixture further contains the yttrium compound, there is no particular limitation regarding the amount of the yttrium compound used. Preferably, the yttrium compound of 5% by mass or less in the form of Y₂O₃, maybe mixed, where the total amount of the raw materials is assumed to be 100% by mass in the forms of oxides. More preferably, the yttrium compound of 0.01% by mass or more and 3% by mass or less in the form of Y₂O₃ may be mixed, where the total amount of the raw materials is assumed to be 100% by mass in the forms of oxides. Further preferably, the yttrium compound of 0.1% by mass or more and 1% by mass or less in the form of Y₂O₃ may be mixed, where the total amount of the raw materials is assumed to be 100% by mass in the forms of oxides, because crystal growth advances more favorably.

The above-described aluminum compound, molybdenum compound, potassium compound, silicon or silicon compound, and metal compound are used such that the total amount of use does not exceed 100% by mass in the forms of oxides.

[Firing Step]

The firing step according to the embodiment is a step of firing the aluminum compound in the presence of the molybdenum compound, the potassium compound, and the silicon or silicon compound. The firing step may be a step of firing the mixture obtained in the mixing step.

The tabular alumina particle according to the embodiment is obtained by, for example, firing the aluminum compound in the presence of the molybdenum compound, the potassium compound, and the silicon or silicon compound. As described above, this manufacturing method is called the flux method.

The flux method is classified in a solution method. In more detail, the flux method is a method for growing a crystal by utilizing a crystal-flux binary phase diagram showing an eutectic type. The mechanism of the flux method is conjectured to be as described below. That is, when a mixture of a solute and a flux is heated, the solute and the flux become a liquid phase. At this time, the flux is a fusing agent, in other words, the solute-flux binary phase diagram shows an eutectic type, and therefore, the solute is fused at a temperature lower than the melting temperature of the solute so as to constitute the liquid phase. When the flux in this state is vaporized, the concentration of the flux decreases, in other words, the effect of decreasing the melting temperature of the solute due to the flux is reduced, and crystal growth of the solute occurs because vaporization of the flux serves as a driving force (flux vaporization method). In this regard, the solute and the flux can also cause crystal growth of the solute by cooling the liquid phase (slow cooling method).

The flux method has advantages of causing crystal growth at a temperature much lower than the melting temperature, controlling the crystal structure precisely, and forming an euhedral polyhedral crystal.

Regarding production of the alumina particle by the flux method in which the molybdenum compound is used as the flux, although the mechanism is not obvious, it is conjectured that the mechanism is, for example, as described below. That is, when the aluminum compound is fired in the presence of the molybdenum compound, aluminum molybdate is formed at first. As is clear from the above description, the aluminum molybdate grows an alumina crystal at a temperature lower than the melting temperature of alumina. Subsequently, the aluminum molybdate is decomposed by, for example, vaporizing the flux, and the alumina particle is obtained by crystal growth. That is, the molybdenum compound serves as the flux, and the alumina particle is produced via aluminum molybdate serving as an intermediate.

In this regard, the tabular alumina particle having a large particle size can be produced by using the potassium compound and the silicon or silicon compound in combination in the flux method. In more detail, when the molybdenum compound and the potassium compound is used in combination, initially, potassium molybdate is formed by a reaction between the molybdenum compound and the potassium compound. At the same time, aluminum molybdate is formed by a reaction between the molybdenum compound and the aluminum compound. Subsequently, for example, aluminum molybdate is decomposed in the presence of potassium molybdate, crystal growth occurs in the presence of the silicon or silicon compound and, thereby, the tabular alumina particle having a large particle size can be produced. That is, when potassium molybdate is present in production of the alumina particle via aluminum molybdate serving as an intermediate, the alumina particle having a large particle size can be produced.

Consequently, although the reason is not obvious, when the alumina particle is obtained based on aluminum molybdate in the presence of potassium molybdate, the alumina particle having a large particle size can be obtained compared with the case in which the alumina particle is obtained based on aluminum molybdate.

Meanwhile, the silicon or silicon compound serving as a shape controlling agent plays an important role in growing a tabular crystal. In generally performed molybdenum oxide flux method, molybdenum oxide selectively adsorbs to the (113) face of an α-crystal of alumina, the crystal component is not readily supplied to the (113) face, and appearance of the (001) face or the (006) face can be completely suppressed. Therefore, a polyhedral particle based on a hexagonal bipyramidal type is formed. Regarding the manufacturing method according to the embodiment, selective adsorption of molybdenum oxide serving as the flux agent to the (113) face is suppressed by using the silicon or silicon compound and, thereby, the (001) face is developed and a tabular form having a crystal structure of hexagonal close-packed lattice that is thermodynamically most stable can be formed.

In this regard, the above-described mechanism is based on conjecture, and even the case in which the effect of the present invention is obtained based on a mechanism different from the above-described mechanism is included in the technical scope of the present invention.

There is no particular limitation regarding the configuration of the potassium molybdate, and usually a molybdenum atom, a potassium atom, and an oxygen atom are included. Preferably, the structural formula is represented by K₂MoₙO₃ₙ₊₁. In this regard, there is no particular limitation regarding n, and the range of 1 to 3 is preferable because facilitation of growth of alumina particle functions effectively. Potassium molybdate may contain other atoms, and examples of the other atoms include sodium, magnesium, and silicon.

In an embodiment according to the present invention, the above-described firing may be performed in the presence of the metal compound. That is, in the firing, the above-described metal compound may be used in combination with the molybdenum compound and the potassium compound. Consequently, the alumina particle having a larger particle size can be produced. Although the mechanism is not obvious, it is conjectured that the mechanism is, for example, as described below. That is, it is considered that when the metal compound is present during crystal growth of the alumina particle, a function of preventing or suppressing formation of alumina crystal nuclei and/or facilitating diffusion of the aluminum compound necessary for crystal growth of alumina, in other words, a function of preventing excessive generation of crystal nuclei and/or increasing the diffusion rate of the aluminum compound is performed, and the alumina particle having a large particle size is obtained. In this regard, the above-described mechanism is based on conjecture, and even the case in which the effect of the present invention is obtained based on a mechanism different from the above-described mechanism is included in the technical scope of the present invention.

There is no particular limitation regarding the firing temperature, and the maximum firing temperature is preferably 700° C. or higher, more preferably 900° C. or higher, further pre0ferably 900° C. to 2,000° C., and particularly preferably 900° C. to 1,000° C. The firing temperature being 700° C. or higher is preferable because a flux reaction advances favorably, and the firing temperature being 900° C. or higher is more preferable because a tabular crystal growth of the alumina particle advances favorably.

There is no particular limitation regarding the states of the aluminum compound, the molybdenum compound, the potassium compound, the silicon or silicon compound, the metal compound, and the like at the time of firing as long as these are mixed. Examples of the mixing method include simple mixing so as to mix powders, mechanical mixing by using a grinder, a mixer, or the like, and mixing by using a mortar or the like. At this time, the resulting mixture may be in any one of a dry state and a wet state, and a dry state is preferable from the viewpoint of cost.

There is no particular limitation regarding the firing time, and 0.1 to 1,000 hours is preferable. From the viewpoint of efficiently forming the alumina particle, 1 to 100 hours is more preferable. The firing time of 0.1 hours or more is preferable because the alumina particle having a large particle size can be obtained. Meanwhile, the firing time of 1,000 hours or less is preferable because the production cost can be reduced.

There is no particular limitation regarding the atmosphere of firing. For example, an oxygen-containing atmosphere such as air or oxygen and an inert atmosphere such as nitrogen or argon are preferable, an oxygen-containing atmosphere and a nitrogen atmosphere having no corrosivity are more preferable from the viewpoint of the safety of an operator and the durability of a furnace, and an air atmosphere is further preferable from the viewpoint of cost.

There is no particular limitation regarding the firing pressure, and the firing may be performed under normal pressure, under pressure, or under reduced pressure. There is no particular limitation regarding heating means, and it is preferable that a firing furnace be used. At this time, examples of the usable firing furnace include a tunnel furnace, a roller-hearth furnace, a rotary kiln, and a muffle furnace.

[Cooling Step]

The manufacturing method according to the present invention may include a cooling step. The cooling step is a step of cooling the alumina crystal grown in the firing step.

There is no particular limitation regarding the cooling rate, and 1° C./hour to 1,000° C./hour is preferable, 5° C./hour to 500° C./hour is more preferable, and 50° C./hour to 100° C./hour is further preferable. The cooling rate being 1° C./hour or more is preferable because the production time is reduced. Meanwhile, the cooling rate being 1,000° C./hour or less is preferable because a firing container does not frequently crack due to heat shock and can be used for a long time.

There is no particular limitation regarding the cooling method, and natural cooling may be adopted or a cooling device may be used.

[Posttreatment Step]

The manufacturing method according to the present invention may include a posttreatment step. The posttreatment step is a step of removing the flux agent. The posttreatment step may be performed after the firing step, performed after the cooling step, or performed after the firing step and the cooling step. As the situation demands, the posttreatment step may be repeated at least two times.

Examples of the posttreatment method include washing and high-temperature treatment. These may be performed in combination.

There is no particular limitation regarding the washing method, and removal can be performed by washing with water, ammonia aqueous solution, sodium hydroxide aqueous solution, or acidic aqueous solution.

At this time, the molybdenum content can be controlled by appropriately changing the concentration and the amount of the water, ammonia aqueous solution, sodium hydroxide aqueous solution, or acidic aqueous solution used, the washing area, the washing time, and the like.

Examples of the high-temperature treatment include a method in which the temperature is increased to the sublimation temperature or boiling temperature of the flux or higher.

[Grinding Step]

Regarding a fired product, in some cases, aggregation of tabular alumina particles occurs and the particle diameters do not fall within the preferable range according to the present invention. Therefore, as the situation demands, grinding may be performed such that the particle diameter of the tabular alumina particle falls within the preferable range according to the present invention.

There is no particular limitation regarding the method for grinding the fired product, and a known method in the related art, for example, a ball mill, a jaw crusher, a jet mill, a disk mill, Spectro Mill, a grinder, or a mixer mill may be applied.

[Classification Step]

Preferably, the tabular alumina particles are subjected to classification treatment for the purpose of adjusting the average particle diameter so as to improve the fluidity of the powder or suppressing a viscosity increase when being mixed into a binder for forming a matrix. The “classification treatment” means an operation to divide particles into groups based on the size of the particle.

The classification may be any one of a wet type and a dry type, and dry type classification is preferable from the viewpoint of productivity. Examples of the dry classification include classification by using a sieve and, in addition, wind power classification in which classification is performed by a difference between centrifugal force and fluid drag. From the viewpoint of classification precision, the wind power classification is preferable and can be performed by using a classifier, for example, a pneumatic classifier by utilizing the Coanda effect, a circular airflow type classifier, a forced vortex centrifugal classifier, or a semi-free vortex centrifugal classifier.

The grinding step and the classification step may be performed at any stage, as the situation demands, that may be before or after an organic-compound-layer-forming step as described later. For example, the average particle diameter of the resulting tabular alumina particles can be adjusted by presence or absence of the grinding and classification and selecting the condition for these.

It is preferable that the tabular alumina particles according to the present invention and the tabular alumina particles obtained by the manufacturing method according to the present invention be aggregated to a less extent or not aggregated because intrinsic properties are readily exhibited, the handleability in themselves is more excellent, and when used after being dispersed in a dispersion medium, more excellent dispersibility is exhibited. Regarding the method for manufacturing the tabular alumina particles, it is preferable that tabular alumina particles with a less extent of aggregation or no aggregation be obtained without performing the grinding step and the classification step because tabular alumina having target excellent properties can be produced with high productivity without performing the above-described steps.

[Organic-compound-layer-forming Step]

In an embodiment, the method for manufacturing the tabular alumina particles may further include the organic-compound-layer-forming step. The organic-compound-layer-forming step is usually performed after the firing step or after the molybdenum removal step.

There is no particular limitation regarding the method for forming the organic compound layer, and a known method may be appropriately adopted. For example, a method in which a liquid containing the organic compound is brought into contact with tabular alumina particles containing molybdenum and drying is performed is adopted.

In this regard, the above-described organic compounds are used as the organic compound used for forming the organic compound layer.

### EXAMPLES

Next, the present invention will be described in further detail with reference to the examples, but the present invention is not limited to the following examples.

[Production of Tabular Alumina Particle]

### Example 1

A mixture was obtained by mixing 50 g of transition alumina (containing γ-alumina as a primary component, the same applies hereafter), 0.025 g of silicon dioxide (produced by KANTO CHEMICAL CO., INC.), 67 g of molybdenum trioxide (produced by TAIYO KOKO CO., LTD.), 32 g of potassium carbonate (produced by KANTO CHEMICAL CO., INC.), and 0.25 g of yttrium oxide (produced by KANTO CHEMICAL CO., INC.) in a mortar. The resulting mixture was placed into a crucible, and firing was performed in a ceramic electric furnace by increasing the temperature to 1,000° C. under the condition of 5° C./min and maintaining at 1,000° C. for 24 hours. Thereafter, the temperature was decreased to room temperature under the condition of 5° C./min, and the crucible was taken out so as to obtain 136 g of light blue powder.

Subsequently, 136 g of the resulting light blue powder was washed by approximately 1% sodium hydroxide aqueous solution. Then, pure water washing was performed while filtration under reduced pressure was continuously performed. Drying was performed at 110° C. so as to obtain 47 g of tabular alumina particles composed of α-alumina that was a light blue powder.

Table 1 shows the amounts (g) of transition alumina, silicon dioxide, molybdenum trioxide, potassium carbonate, and yttrium oxide mixed and the mixing ratio in the mixture. “Mo/Al molar ratio” represents the molar ratio (molybdenum element/aluminum element) of the molybdenum element in the molybdenum compound to the aluminum element in the aluminum compound. “Mo/K molar ratio” represents the molar ratio (molybdenum element/potassium element) of the molybdenum element in the molybdenum compound to the potassium element in the potassium compound. “Amount added to Al₂O₃” of the silicon compound represents the ratio of the silicon compound added relative to the aluminum atom in the aluminum compound in terms of mass. “Amount added to Al₂O₃” of the yttrium compound represents the ratio of the yttrium compound added relative to the aluminum atom in the aluminum compound in terms of mass.

### Examples 2 to 7

Tabular alumina particles composed of α-alumina were produced in the same manner as example 1 described above except that the amounts of transition alumina, molybdenum trioxide, potassium carbonate, silicon dioxide, and yttrium oxide mixed in example 1 were changed as shown in Table 1.

In this regard, no yttrium compound was detected from each of the tabular alumina particles produced by also using the yttrium compound as the metal compound because the yttrium compound was removed by washing.

TABLE 1

| | | | | | | | | | | Comparative | |
|---|---|---|---|---|---|---|---|---|---|---|---|
| | | | Examples | | | | | | | examples | |
| | | | 1 | 2 | 3 | 4 | 5 | 6 | 7 | 1 | 2 |
| Actual | Transition | Al₂O₃ | 50 | 50 | 80 | 80 | 65 | 80 | 50 | 50 | — |
| mixing | alumina | | | | | | | | | | |
| | Aluminum | Al(OH)₃ | — | — | — | — | — | — | — | — | 77 |
| | hydroxide | | | | | | | | | | |
| | Molybdenum | MoO₃ | 67 | 67 | 108 | 108 | 58 | 150 | 45 | 67 | 50 |
| | trioxide | | | | | | | | | | |
| | Potassium | K₂CO₃ | 32 | 32 | 51 | 51 | 28 | 72 | 22 | 32 | — |
| | carbonate | | | | | | | | | | |
| | Silicon | SiO₂ | 0.025 | 0.05 | 0.2 | 0.4 | 0.16 | 0.2 | 0.2 | — | 0.1 |
| | dioxide | | | | | | | | | | |
| | Yttrium | Y₂O₃ | 0.25 | 0.25 | 0.4 | 0.4 | 0.32 | 0.4 | — | 0.25 | — |
| | oxide | | | | | | | | | | |
| Ratio | Molybdenum | Mo/Al molar | 0.47 | 0.47 | 0.47 | 0.47 | 0.32 | 0.66 | 0.32 | 0.47 | 0.35 |
| | compound | ratio | | | | | | | | | |
| | Potassium | Mo/K molar | 1 | 1 | 1 | 1 | 1 | 1 | 1 | 1 | — |
| | compound | ratio | | | | | | | | | |
| | Silicon | Amount added | 0.05 | 0.1 | 0.25 | 0.5 | 0.25 | 0.25 | 0.1 | — | 0.2 |
| | compound | to Al₂O₃ | | | | | | | | | |
| | | (% by mass) | | | | | | | | | |
| | Yttrium | Amount added | 0.5 | 0.5 | 0.5 | 0.5 | 0.5 | 0.5 | 0 | 0.5 | — |
| | compound | to Al₂O₃ | | | | | | | | | |
| | | (% by mass) | | | | | | | | | |

*In the table, the value of Actual mixing is expressed in gram (g).

### Comparative Example 1

A mixture was obtained by mixing 50 g of transition alumina, 67 g of molybdenum trioxide (produced by TAIYO KOKO CO., LTD.), 32 g of potassium carbonate (produced by KANTO CHEMICAL CO., INC., Cica first grade), and 0.25 g of yttrium oxide (produced by KANTO CHEMICAL CO., INC.) in a mortar. The resulting mixture was placed into a crucible, and firing was performed in a ceramic electric furnace by increasing the temperature to 1,000° C. under the condition of 5° C./min and maintaining at 1,000° C. for 24 hours. Thereafter, the temperature was decreased to room temperature under the condition of 5° C./min, and the crucible was taken out so as to obtain 136 g of light blue powder.

Subsequently, 136 g of the resulting light blue powder was washed by approximately 1% sodium hydroxide aqueous solution. Then, pure water washing was performed while filtration under reduced pressure was continuously performed. Drying was performed at 110° C. so as to obtain 48 g of polyhedral alumina that was a light blue powder.

The XRD measurement was performed. As a result, sharp peak scattering attributed to α-alumina appeared, no peak of alumina crystal other than the α-crystal structure was observed, and a dense crystal structure was identified. In addition, from the result of X-ray fluorescence quantitative analysis, it was identified that the resulting particle contained molybdenum of 0.2% in the form of molybdenum trioxide.

### Comparative Example 2

A mixture was obtained by mixing 77.0 g of aluminum hydroxide (produced by Nippon Light Metal Company, Ltd., average particle diameter of 10 μm), 0.1 g of silicon dioxide (produced by KANTO CHEMICAL CO., INC., analytical grade), and 50.0 g of molybdenum trioxide (produced by TAIYO KOKO CO., LTD.) in a mortar. The resulting mixture was placed into a crucible, and firing was performed in a ceramic electric furnace at 1,100° C. for 10 hours. The temperature was decreased and, thereafter, the crucible was taken out so as to obtain 52 g of light blue powder. The resulting powder was disintegrated so as to pass through a 106-μm sieve).

Subsequently, 52.0 g of the resulting light blue powder was dispersed into 150 mL of 0.5% ammonia water, the dispersion solution was agitated at room temperature (25° C. to 30° C.) for 0.5 hours, the ammonia water was removed by filtration, and molybdenum remaining on the particle surface was removed by performing water washing and drying so as to obtain 51.2 g of blue powder.

XRD measurement was performed. As a result, sharp peak scattering attributed to α-alumina appeared, no peak of alumina crystal other than α-crystal structure was observed, and tabular alumina having a dense crystal structure was identified. In addition, from the result of X-ray fluorescence quantitative analysis, it was identified that the resulting particle contained molybdenum of 1.39% in the form of molybdenum trioxide.

This comparative example 1 corresponds to example 1 of Japanese Unexamined Patent Application Publication No. 2016-222501 cited as PTL 2.

[Evaluation]

Samples of the powders produced in examples 1 to 7 and comparative examples 1 and 2 were subjected to the following evaluations. The measuring methods are as described below.

[Measurement of Major Axis L of Tabular Alumina]

Major axes of 50 particles were measured by using a scanning electron microscope (SEM) and the average value was assumed to be the major axis L (μm).

[Measurement of Thickness D of Tabular Alumina]

Thicknesses of 50 particles were measured by using a scanning electron microscope (SEM) and the average value was assumed to be the thickness D (μm).

[Aspect Tatio L/D]

The aspect ratio was determined by using the following formula. aspect ratio=(major axis L of tabular alumina)/(thickness D of tabular alumina)

[Evaluation of Shape of Tabular Alumina]

The shapes of alumina particles were examined based on the images obtained by using a scanning electron microscope (SEM). The case in which 5% or more of hexagonal-plate-like particles in number were observed, where the total number of alumina particles with the shapes examined were assumed to be 100%, was rated that hexagonal-plate-like alumina particles were “present” (“+” or “++”).

[XRD Analysis]

The sample was placed on a measurement sample holder having a depth of 0.5 mm so as to be flattened with a predetermined load, the resulting holder was set into a wide-angle X-ray diffraction (XRD) apparatus (Rint-Ultma produced by Rigaku Corporation), and measurement was performed under the conditions of Cu/Ka rays, 40 kV/30 mA, scan speed of 2 degrees/min, and a scanning range of 10 to 70 degrees. [Analysis of Amount of Si in Tabular Alumina Particle Surface Layer]

The prepared sample was press-fixed on a double-faced tape, and composition analysis was performed under the conditions described below by using an X-ray photoelectron spectroscopy (XPS) apparatus Quantera SNM (ULVAC-PHI, Inc.). X-ray source: monochromatic AlKa, beam diameter of 100 μm, and output of 25 W

Measurement: area measurement (1,000 μm square) and n=3 Charge correction: C1s=284.8 eV

The amount of Si in the tabular alumina particle surface layer was assumed to be [Si]/[Al] determined from the result of XPS analysis. [Analysis of Amount of Si Contained in Tabular Alumina Particle]

Approximately 70 mg of the prepared sample was placed on filter paper and covered with a PP film, and composition analysis was performed by using X-ray fluorescence (XRF) analysis apparatus Primus IV (produced by Rigaku Corporation).

The amount of Si in the tabular alumina particle was assumed to be [Si]/[Al] determined from the result of XRF analysis.

The amount of silicon determined from the result of XRF analysis was converted to silicon dioxide (% by mass) relative to 100% by mass of the tabular alumina particle.

[Analysis of Amount of Mo Contained in Tabular Alumina]

Approximately 70 mg of the prepared sample was placed on filter paper and covered with a PP film, and composition analysis was performed by using X-ray fluorescence analysis apparatus Primus IV (produced by Rigaku Corporation).

The amount of molybdenum determined from the result of XRF analysis was converted to molybdenum trioxide (% by mass) relative to 100% by mass of the tabular alumina particle.

[Crystallite Diameter]

Measurement was performed by using SmartLab (produced by Rigaku Corporation) serving as an X-ray diffraction apparatus, using a high-intensity high-resolution crystal analyzer (CALSA) serving as a detector, and using PDXL serving as analysis software. At this time, the measuring method was the 2θ/θ method, and regarding the analysis, calculation was performed, by using Scherrer equation, based on the full-widths at half-maximum of peaks that appeared at approximately 2θ=35.2° ([104] face) and approximately 2θ=43.4° ([113] face). Regarding the measurement conditions, the scan speed was 0.05 degrees/min, the scan range was 5 to 70 degrees, the step was 0.002 degrees, and the apparatus standard width was 0.027° (Si).

[Single Crystal Measurement]

Structural analysis of tabular α-alumina was performed by using a single crystal X-ray diffractometer for chemical crystallography XtaLab P200 (produced by Rigaku Corporation). The measurement conditions and various types of software used for analysis are as described below.

Apparatus: XtaLab P200 produced by Rigaku Corporation (detector: PIRATUS 200K)

Measurement conditions:

radiation source of Mo Kα (λ=0.7107 angstrom)

X-ray output: 50 kV−24 mA

blowing gas: N₂, 25° C.

camera length: 30 mm

Measurement software: CrystalClear

Image processing software: CrysAlis Pro

Structural analysis software: olex2, SHELX

The measurement result was subjected to structural analysis, and the image subjected to the image processing was visually observed. The case in which a regular arrangement with no distortion was identified was rated as a single crystal.

[Evaluation of Brilliance]

The powder was observed by the naked eye and evaluated based on the following criteria.

o: intense reflection of glittering light that is derived from the powder can be observed

x: no reflection of glittering light that is derived from the powder can be observed

[Alpha-crystal Ratio]

The prepared sample was placed on a measurement sample holder having a depth of 0.5 mm so as to be flattened with a predetermined load, the resulting holder was set into a wide-angle X-ray diffraction apparatus (Rint-Ultma produced by Rigaku Corporation), and measurement was performed under the conditions of Cu/Kα rays, 40 kV/30 mA, scan speed of 2 degrees/min, and a scanning range of 10 to 70 degrees. The α-crystal ratio was determined from the ratio of the most intense peak height of α-alumina to transition alumina.

The mixing ratio of the raw material compounds in the forms of oxides (the total was set to be 100% by mass) and results of the evaluation are shown in Table 2.

TABLE 2

| | Form of | | | | | | | | Comparative | Comparative |
|---|---|---|---|---|---|---|---|---|---|---|
| | oxide | Example 1 | Example 2 | Example 3 | Example 4 | Example 5 | Example 6 | Example 7 | example 1 | example 2 |
| Mixing | Al₂O₃ | 37.07 | 37.07 | 36.93 | 36.89 | 46.80 | 29.61 | 46.84 | 37.08 | 50.1 |
| | MoO₃ | 49.68 | 49.67 | 49.85 | 49.80 | 41.76 | 55.52 | 42.16 | 49.69 | 49.8 |
| | K₂O | 13.05 | 13.05 | 12.95 | 12.93 | 11.09 | 14.65 | 10.82 | 13.05 | — |
| | SiO₂ | 0.02 | 0.04 | 0.09 | 0.18 | 0.12 | 0.07 | 0.19 | — | 0.1 |
| | Y₂O₃ | 0.19 | 0.19 | 0.18 | 0.18 | 0.23 | 0.15 | — | 0.19 | — |

| | | | | | | | | | |
|---|---|---|---|---|---|---|---|---|---|
| L [μm] | 80 | 88 | 85 | 67 | 80 | 95 | 84 | 65 | 10.1 |
| D [μm] | 20 | 15 | 11 | 7 | 9 | 12 | 13 | 65 | 0.5 |
| Aspect ratio L/D | 4 | 6 | 8 | 10 | 9 | 8 | 6 | 1 | 20 |
| Hexagonal-plate- | ++ | ++ | + | + | + | ++ | + | − | − |
| like shape | | | | | | | | | |
| XPS molar ratio | 0.0220 | 0.0288 | 0.0439 | 0.0804 | 0.0459 | 0.0432 | 0.0224 | N.D. | 0.11 |
| [Si]/[Al] | | | | | | | | | |
| XRF molar ratio | 0.00062 | 0.00086 | 0.00182 | 0.00303 | 0.00180 | 0.00189 | 0.00087 | N.D. | 0.002 |
| [Si]/[Al] | | | | | | | | | |
| XRF SiO₂ (% by | 0.06 | 0.1 | 0.21 | 0.35 | 0.22 | 0.2 | 0.1 | N.D. | 0.21 |
| mass) | | | | | | | | | |
| XRF MoO₃ (% by | 0.4 | 0.44 | 0.92 | 1.61 | 0.88 | 0.92 | 0.42 | 0.2 | 1.39 |
| mass) | | | | | | | | | |
| (104) Face | 515 | 543 | 374 | 188 | 240 | 386 | 538 | 260 | 125 |
| crystallite | | | | | | | | | |
| diameter [nm] | | | | | | | | | |
| (113) Face | 371 | 687 | 321 | 250 | 216 | 353 | 664 | 314 | 159 |
| crystallite | | | | | | | | | |
| diameter [nm] | | | | | | | | | |
| Single crystal | ∘ | ∘ | ∘ | ∘ | ∘ | ∘ | ∘ | ∘ | *1 |
| Brilliance | ∘ | ∘ | ∘ | ∘ | ∘ | ∘ | ∘ | x | x |

*1: Measurement was impossible.

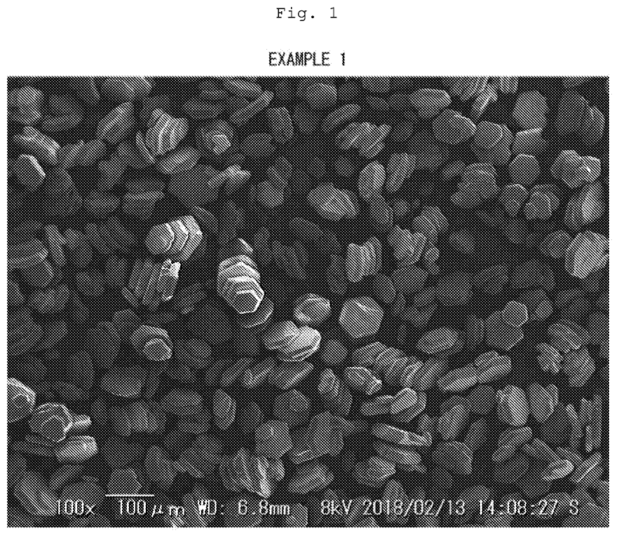

FIG. 1 shows the SEM image of tabular alumina particles in example 1.

It was determined that the powders obtained in examples 1 to 7 and comparative example 1 and 2 had the thicknesses, average particle diameters, and aspect ratios described in Table 2.

Regarding the particle shape, images obtained from a plurality of SEM images of the sample in arbitrary field of view were observed. In table 2, regarding the samples rated that hexagonal-plate-like alumina particles were “present”, the sample in which the proportion of hexagonal-plate-like particles observed was 80% or more in number, where the total number of tabular alumina particles was assumed to be 100%, was expressed as “++” and the sample in which the proportion of hexagonal-plate-like particles was 30% or more was expressed as “+”. Hexagonal-plate-like particles were identified in examples 1 to 7.

In examples 1 to 7, it was ascertained that the proportion of hexagonal-plate-like particles increased as the [Mo]/[Al] molar ratio increased, and that the proportion of hexagonal-plate-like particles decreased as the amount of silicon compound added increased. Further, the range of the amount of silicon compound added for the purpose of increasing the content of hexagonal-plate-like particles was changed by the [Mo]/[Al] molar ratio.

The powders obtained in examples 1 to 7 and comparative examples 1 and 2 were subjected to the XRD measurement. As a result, sharp peak scattering attributed to α-alumina appeared, no peak of alumina crystal other than the α-crystal structure was observed, and tabular alumina having a dense crystal structure was identified. Therefore, it was determined that the α-crystal ratios of the powders obtained in examples 1 to 7 and comparative examples 1 and 2 were 90% or more.

In examples 1 to 7, the α-crystal ratio was 90% or more and, therefore, intense reflection of light was ascertained in contrast to the raw materials.

In addition, single crystal X-ray analysis was performed. The measurement result obtained in each of examples 1 to 7 was subjected to structural analysis, and the image subjected to the image processing was visually observed. As a result, a regular arrangement with no distortion was identified and, therefore, it was determined that the particle was a single crystal.

In examples 1 to 7, the tabular alumina crystals were not only substantially α-type but also single crystals, and the contents of hexagonal-plate-like shapes were high. Therefore, it was ascertained that intense reflection of glittering light derived from the powder was exhibited and the brilliance was excellent.

Regarding the powders obtained in examples 1 to 7, presence of mullite was not identified by the XRD analysis.

As is clear from comparisons of examples 1 to 7 with comparative examples 1 and 2, the tabular alumina crystals in examples 1 to 7 had a major axis of 30 μm or more, a thickness of 3 μm or more, and an aspect ratio of 2 to 50 and exhibited more excellent brilliance than the alumina particles in comparative examples 1 and 2 that did not satisfy the above-described factors.

As is clear from comparisons of examples 1 to 7 with comparative example 1, the alumina particles that were produced by using SiO2 serving as the raw material in examples 1 to 7 had aspect ratios of 2 or more and were tabular, whereas the alumina particle of comparative example 1 that was produced by using no SiO₂ serving as the raw material had an aspect ratio of less than 2 and did not have a tabular structure. In addition, it was found that the aspect ratio increased as the amount of SO₂ included in the raw material increased in examples 1 to 6. The tabular alumina particles having aspect ratios of 2 or more in examples 1 to 7 had excellent brilliance.

As is clear from comparisons of examples 1 to 7 with comparative example 2, the tabular alumina particles having a crystallite diameter of the (104) face of 150 nm or more or a crystallite diameter of the (113) face of 200 nm or more in examples 1 to 7 had more excellent brilliance than the alumina particle that did not satisfy the above-described factor in comparative example 2.

As is clear from comparisons of examples 1 to 6 with comparative examples 1 and 2, the tabular alumina particles produced by using Al₂O₃, MoO₃, K₂CO₃, SiO₂, and Y₂O₃ serving as raw materials in examples 1 to 6 were tabular and had larger particle sizes, larger crystallite diameters, and more excellent brilliance than the alumina particles produced without using these compounds in comparative examples 1 and 2.

Referring to examples 1 to 6, in examples 1 and 2 and example 6, it was found that when the amount of molybdenum serving as the raw material was increased and the amount of silicon serving as the raw material was decreased, the hexagonal-plate-like alumina particle was readily obtained and, in addition, the hexagonal-plate-like alumina particles having larger particle size and larger crystallite diameter and exhibiting particularly excellent brilliance were obtained.

Presence of Si and Mo derived from the raw materials in the produced tabular alumina particles was identified by the XPS analysis and the XRF analysis. In this regard, Si and Mo in the raw materials tended to be contained into the particles in accordance with the amounts of the raw materials used.

Each configuration of each of the above-described embodiments or a combination or the like of the configurations is an example, and addition, omission, substitution, and other changes of the configuration may be performed within the bounds of not departing from the gist of the present invention. The present invention is not limited to each embodiment and is only defined by the scope of the claims.

### INDUSTRIAL APPLICABILITY

According to the present invention, the tabular alumina particle having a more excellent feeling of brilliance than tabular alumina particles in the related art can be provided by having a predetermined shape.

1. A tabular alumina particle having a major axis of 30 μm or more, a thickness of 3 μm or more, and an aspect ratio of 2 to 50 and comprising molybdenum.

2. The tabular alumina particle according to claim 1, further comprising silicon.

3. The tabular alumina particle according to claim 2, wherein a molar ratio [Si]/[Al] of Si to Al, determined based on XPS analysis, is 0.001 or more.

4. The tabular alumina particle according to claim 1, wherein a crystallite diameter of a (104) face is 150 nm or more, the crystallite diameter being calculated from a full-width at half-maximum of a peak corresponding to a (104) face of diffraction peaks obtained based on XRD analysis.

5. The tabular alumina particle according to claim 1, wherein a crystallite diameter of a (113) face is 200 nm or more, the crystallite diameter being calculated from a full-width at half-maximum of a peak corresponding to a (113) face of diffraction peaks obtained based on XRD analysis.

6. The tabular alumina particle according to claim 1, wherein a shape is a hexagonal-plate-like shape.

7. The tabular alumina particle according to claim 1, wherein the tabular alumina particle is a single crystal.

8. A method for manufacturing a tabular alumina particle according to claim 1, the method comprising the steps of mixing an aluminum compound containing aluminum element of 10% by mass or more in a form of Al₂O₃, a molybdenum compound containing molybdenum element of 20% by mass or more in a form of MoO₃, a potassium compound containing potassium element of 1% by mass or more of in a form K₂O, and silicon or a silicon compound containing silicon element of less than 1% by mass in a form of SiO₂, where a total amount of raw materials is assumed to be 100% by mass in forms of oxides, so as to produce a mixture and firing the resulting mixture.

9. The method for manufacturing a tabular alumina particle according to claim 8, in which the mixture further includes an yttrium compound containing an yttrium element.
